(19) United States
(12) Patent Application Publication
(10) Pub. No.: US 2007/0241435 A1
(43) Pub. Date: Oct. 18, 2007

(54) Optical display package and the method thereof

(75) Inventors: Chih-Yuan Wang, Taichung County (TW); Heng-Yi Chang, Taipei City (TW); Ya-Ling Hsu, Changhua County (TW); Yi-Te Lee, Kaohsiung City (TW)

Correspondence Address: BACON & THOMAS, PLLC, 625 SLATERS LANE, FOURTH FLOOR, ALEXANDRIA, VA, 22314, US

(73) Assignee: WINTEK CORPORATION, TAICHUNG (TW)

(21) Appl. No.: 11/580,124

(22) Filed: Oct. 13, 2006

(30) Foreign Application Priority Data
Apr. 12, 2006 (TW) 95113048

(51) Int. Cl. H01L 23/02

(52) U.S. Cl. 257/678

(57) ABSTRACT

The present invention includes a substrate with a glass plate, a plurality of oxide wires on the glass plate and a plurality of flip chip bumps on the oxide wires and an integrated circuit chip with a plurality of bump pads. The substrate and the integrated circuit chip are hot pressed with a predetermined bonding pressure and temperature to bond the bump pads to the flip chip bumps respectively by eutectic bonding.

### BACKGROUND OF THE INVENTION

1. Field of the Invention

The present invention relates generally to an electric device package, and more particularly to an optical display package.

2. Description of the Related Art

FIG. 1 is a schematic drawing showing a conventional optical display package 1, which includes a glass substrate 2, a driving IC 3, an anisotropic conductive film (ACF) 4. The glass substrate 2 is provided with a plurality of indium tin oxide (ITO) conductive films 2a. The driving IC is provided with a plurality of bumps 3a. The ACF conductive film 4, which includes a plurality of conductive particles 4a therein, attaches the driving IC 3 on the glass substrate 2. To attach the driving IC 3 on the glass substrate 2, the ITO conductive films 2a are aligned with the bumps 3a respectively and compressed for electrical conduction by the conductive particles 4a. In the present days, the displays are designed to have smaller size and multifunction so that intervals between the bumps 3a are shortened to make the driving IC 3 having more bumps 3a. For the driving IC 3 with crowded bumps 3a, the conductive particles 4a between the bumps 3a may push and contact with each other that may cause the neighboring bumps 3a short. In addition, the conductive particles 4a between the bumps 3a and the conductive films 2a may be broken by the compressing force that may cause failure in electrical conduction between the ITO conductive films 2a and the bumps 3a.

FIG. 2 is a sketch diagram showing another problem of the conventional optical display package 1. After the process of compressing the driving IC 3 and the glass substrate 2, some conductive particles 4a′ may be deformed because of lack of elasticity. Such conductive particles 4a′ may not contact the bumps 3a with the ITO conductive films 2a to cause a broken circuit.

To overcome the problems above, an improved optical display package 1′ was provided, which includes a non-conductive film (NCF) 5 between a glass substrate 6 and a driving IC 7. The NCF 5 has no conductive particle. The package 1′ further provides combination type bumps 7 on an ITO conductive film 6a of the glass substrate 6. The combination type bump 7 consists of an elastic member 7a and a metal foil 7b covering the entire elastic member 7a. In the process of pressing the driving IC 8 onto the glass substrate 6, the combination type bumps 7 are contacted with bumps 9 of the driving IC 8. As the driving IC 8 closes to the glass substrate 6, the elastic members 7a of the combination type bumps 7 are deformed, so that the metal foils 7b have more areas contacted the bumps 9 for electrical conduction. Although, the combination type bumps 7 may make sure of conduction with the bumps 9, the pressure still may break the metal foils 7b that make failure of conduction.

### SUMMARY OF THE INVENTION

The primary objective of the present invention is to provide an optical display package, which electrically connecting two electric devices by eutectic bonding technique to get a well electrical conduction therebetween.

According to the objective of the present invention, the present invention provides a substrate with a glass plate, a plurality of oxide wires on the glass plate and a plurality of flip chip bumps on the oxide wires and an integrated circuit chip with a plurality of bump pads. The substrate and the integrated circuit chip are hot pressed with a bonding pressure less than 400 MPa and a bonding temperature less than 400° C. to bond the bump pads to the flip chip bumps respectively by eutectic bonding.

### BRIEF DESCRIPTION OF THE DRAWINGS

FIG. 1 is a schematic diagram of the conventional liquid crystal display, showing the driving IC connecting the glass substrate by anisotropic conductive film;

FIG. 2 is a similar to FIG. 1, showing the conductive particles causing a bad electrical connection;

FIG. 3 is a schematic diagram of the conventional liquid crystal display, showing the driving IC connecting the glass substrate by non-conductive film;

FIG. 4 is a schematic diagram of a first preferred embodiment of the present invention, showing the preassembled liquid crystal display package;

FIG. 5 is an exploded view of the first preferred embodiment of the present invention, showing the liquid crystal display package going to be assembled;

FIG. 6 is a schematic diagram of the first preferred embodiment of the present invention, showing the assembled liquid crystal display package;

FIG. 7 shows the bump pad made of tin/chromium alloy;

FIG. 8 is a schematic diagram of a second preferred embodiment of the present invention, showing the flip chip bump with a closed chamber therein;

FIG. 9 is a sectional view of the second preferred embodiment of the present invention;

FIG. 10 is similar to FIG. 9, showing the lip chip bump having two lateral bores communicated with the chamber;

FIG. 11 shows an insulating member received in the chamber of FIG. 9;

FIG. 12 shows the bump pad with closed chamber therein;

FIG. 13 shows the bump pad having two lateral bores communicated with the chamber; and

FIG. 14 shows an insulating member received in the chamber of the bump pad of FIG 12.

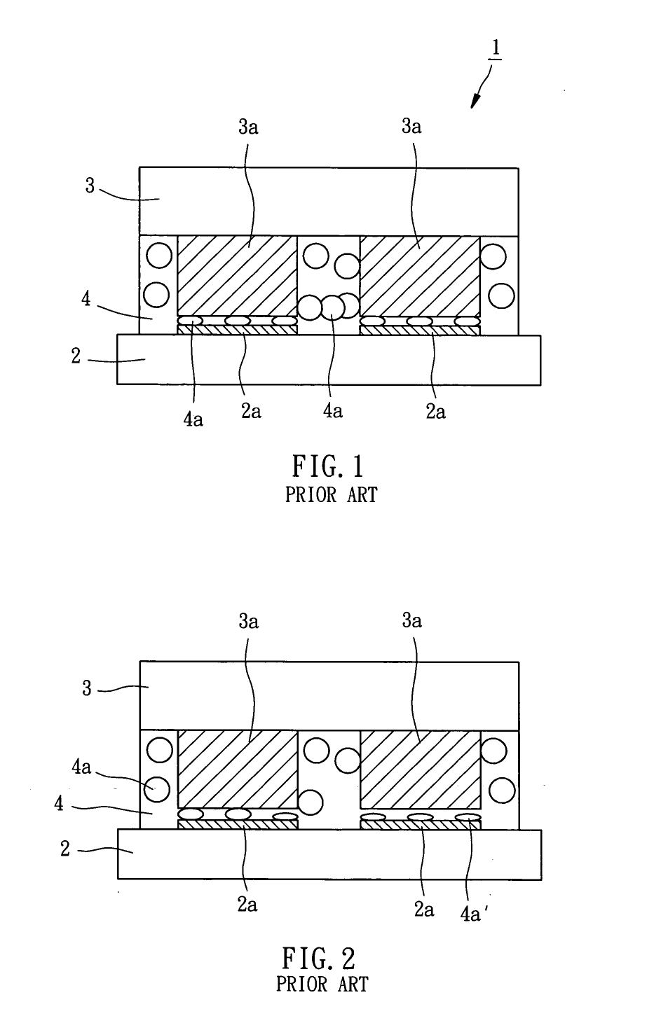

### DETAILED DESCRIPTION OF THE INVENTION

FIGS. from 4 to 6 show an optical display package 10 of the first preferred embodiment of the present invention and the package method.

The optical display package 10 includes a substrate 12 and an integrated circuit chip 14.

The substrate 12 includes a glass plate 121, a plurality of oxide wires 122 and a plurality of flip chip bumps 123. The oxide wires 122, which ITO film, are provided on the glass plate 121, and the flip chip bumps 123 are protrusions on the oxide wires 122 with an edge side 123a respectively. In the present invention, the flip chip bumps 123 are made of gold.

The integrated circuit chip 14 is provided with bump pads 141 associated with the flip chip bumps 123 respectively. In the present invention, the bump pads 141 are made of gold with an edge side 141a respectively.

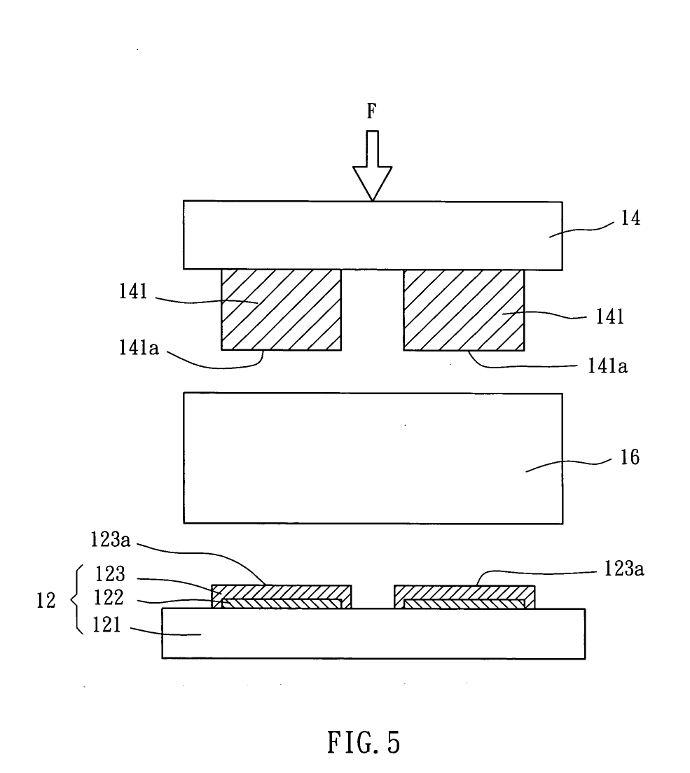

The optical display package 10 of the present invention has the integrated circuit chip 14 bonded to the substrate 12 by flip chip technique. As shown in FIG. 4, the bump pads 141 of the integrated circuit chip 14 are aligned with the flip chip bumps 123 of the substrate 12, then a non-conductive film 16 is provided between the integrated circuit chip 14 and the substrate 12, as shown in FIG. 5. A pressure F less than 500 MPa is applied on the integrated circuit chip 14 to contact the edge sides 123a of the flip chip bumps 123 of the substrate 12 with the edge sides 141a of the bump pads 141 of the integrated circuit chip 14 respectively. In the same time, the integrated circuit chip 14 and the substrate 12 are heated in a predetermined temperature less than 400° C. to make the bump pads 141 and the flip chip bumps 123 thermoplastic deformation at contact portions thereof, and it occurs atom-stage bonding at the edge sides 141a and 123a. In other words, it occurs eutectic bonding between the gold atoms of the edge sides 141a and 123a by forming chemical bonds therebetween. After that, the temperature is lowed to have a firm bonding of the bump pads 141 and the flip chip bumps 123 and the solidified non-conductive film 16 to achieve the results of package and electrical connection.

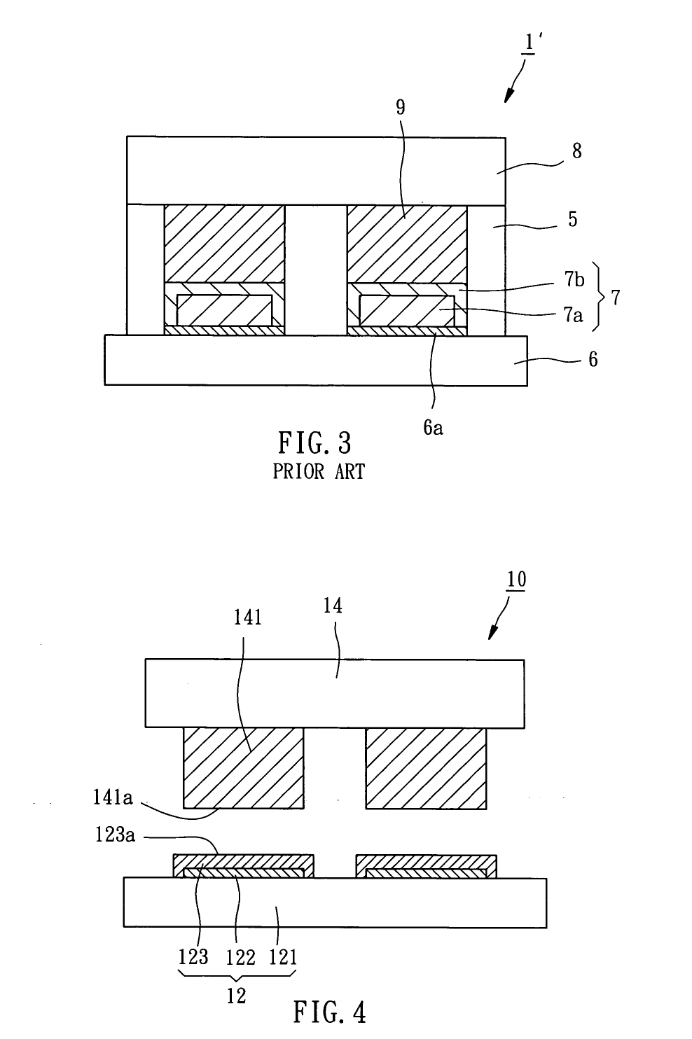

In conclusion, the present invention provides an electrical conduction between two fine electric devices by direct connection of the bump pads 141 and the flip chip bumps 123. The eutectic bonding is occurred between the bump pads 141 and the flip chip bumps 123 under a predetermined bonding temperature. Such structure overcomes the short problem of the anisotropic conductive film. Furthermore, the non-conductive film 16 used the present invention is cheaper than the anisotropic conductive film. In addition, the present invention provides the flip chip bumps 123 on the oxide wires 122 for eutectic bonding. The bump pads 141 are inserted into the flip chip bumps 123 respectively when the integrated circuit chip 14 is pressed onto the substrate 12 so that the present invention has no break problem of the conventional combination type bumps 7 shown in FIG. 3. As a result, the present invention uses the eutectic bonding to electrically conduct two electric devices, and the electric devices have well conduction.

In the present invention, the bump pads 141 and the flip chip bumps 123 are made of gold, in fact, the bump pads 141 and the flip chip bumps 123 may be made of silver, copper, tin, nickel, aluminum, lead, and the alloy thereof. For eutectic bonding, the bonding temperature (melting temperature) should reach a temperature making two bonding materials generating chemical bonds for bonding. For example, when the bump pad is made of gold and the flip chip bump is made of tin (the melting temperature of tin is lower than that of gold), the bonding temperature (melting temperature of tin is 231.97° C.) of eutectic bonding has to spread the tin atoms to the gold atoms and generate chemical bonds for bonding. FIG. 7 shows a combination type flip chip bump 17, which has a chromium layer 172 covered by a tin layer 171. The chromium layer 172 has well conduction to be a well bonding interlayer between the tin layer 171 and the oxide wire 122. If the bump pad 141 is made of gold, the bonding temperature for eutectic bonding is associated with the melting temperature of tin.

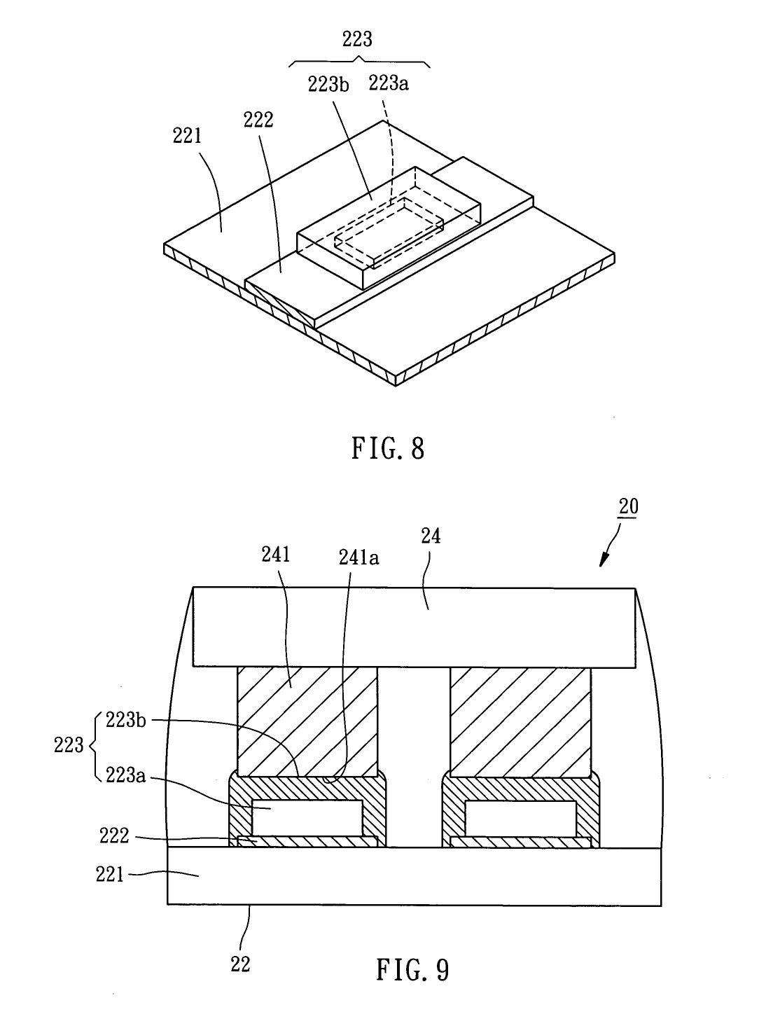

As shown in FIG. 8 and FIG. 9, an optical display package 20 of the second preferred embodiment, which is similar to the first preferred embodiment, includes a substrate 22 and an integrated circuit chip 24. The substrate 22 includes a glass plate 221 and a plurality of oxide wires 222. The integrated circuit chip 24 includes a plurality of bump pads 241. The different parts of the second preferred embodiment include:

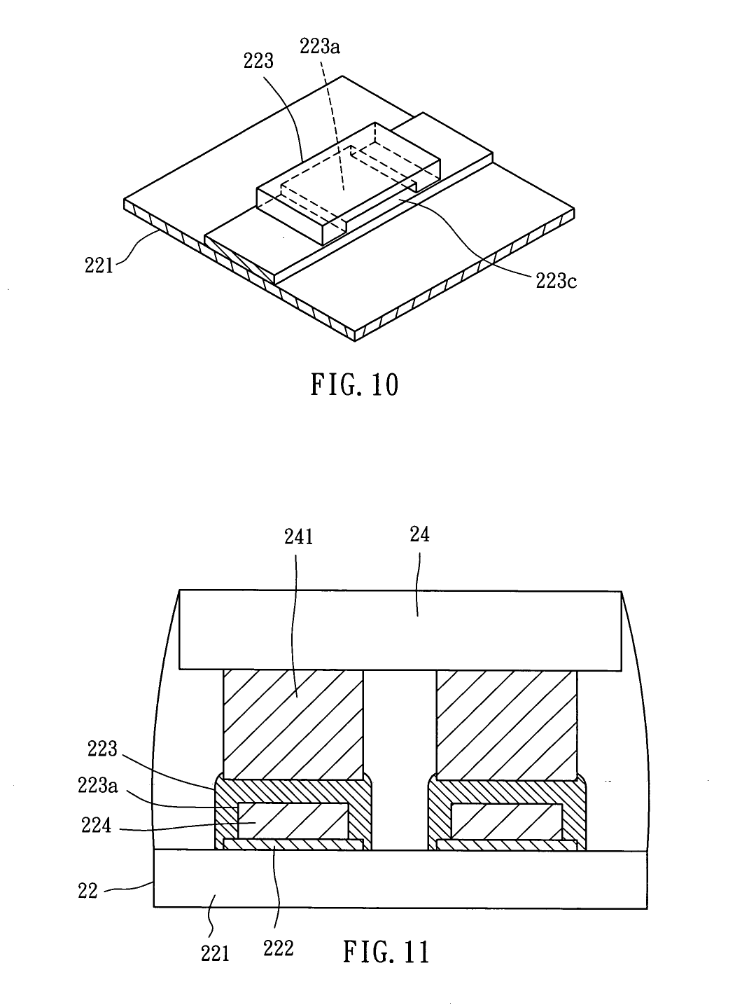

Each of flip chip bumps 223 on the oxide wires 222 has a chamber 223a therein. In the hot press of the substrate 22 and the integrated circuit chip 24, eutectic bonding is occurred between edge sides 223b and 241a of the flip chip bumps 223 and the bump pads 241. In the same time, the chambers 223a help the flip chip bumps 223 extension and deformation to increase the contact area and get a well conduction condition. FIG. 10 shows the flip chip bump 223 further includes two lateral bores 223c communicated with the chamber 223a that escape gas in the chamber out when the flip chip bump 223 is pressed by the bump pad 241.

In addition, FIG. 11 shows the flip chip bump 223 further includes an insulating member 224 received in the chamber 223a. The insulating member 224 is made of a flexible material to absorb the pressure of hot press that reduces the impact of the bump pad 241 on the flip chip bump 223 and keeps a well eutectic bonding condition.

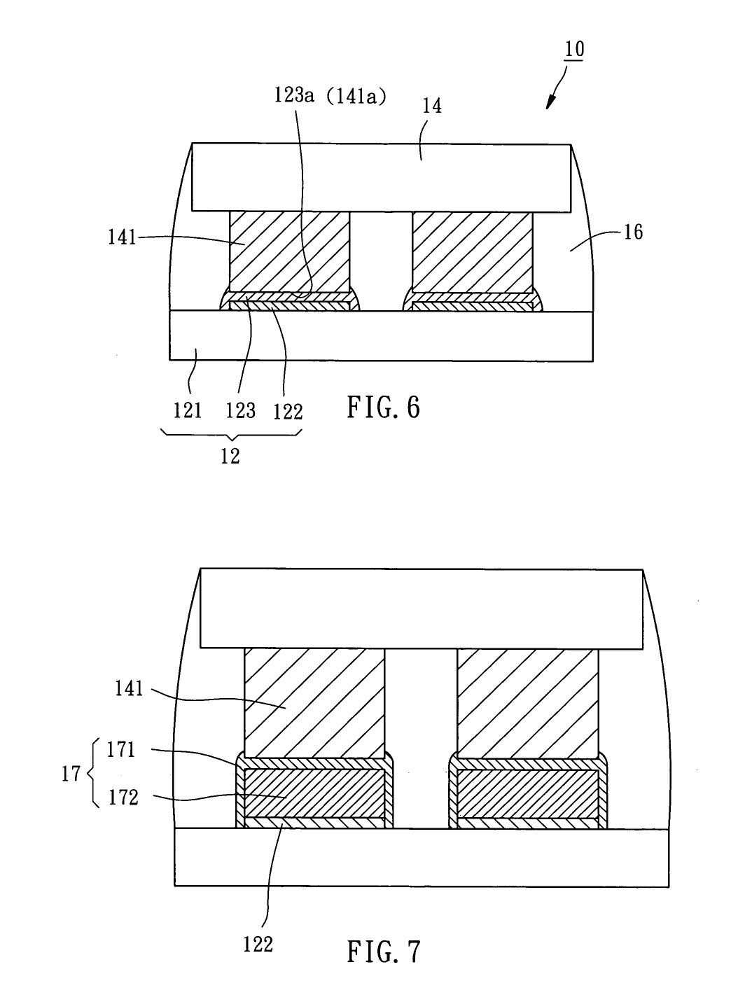

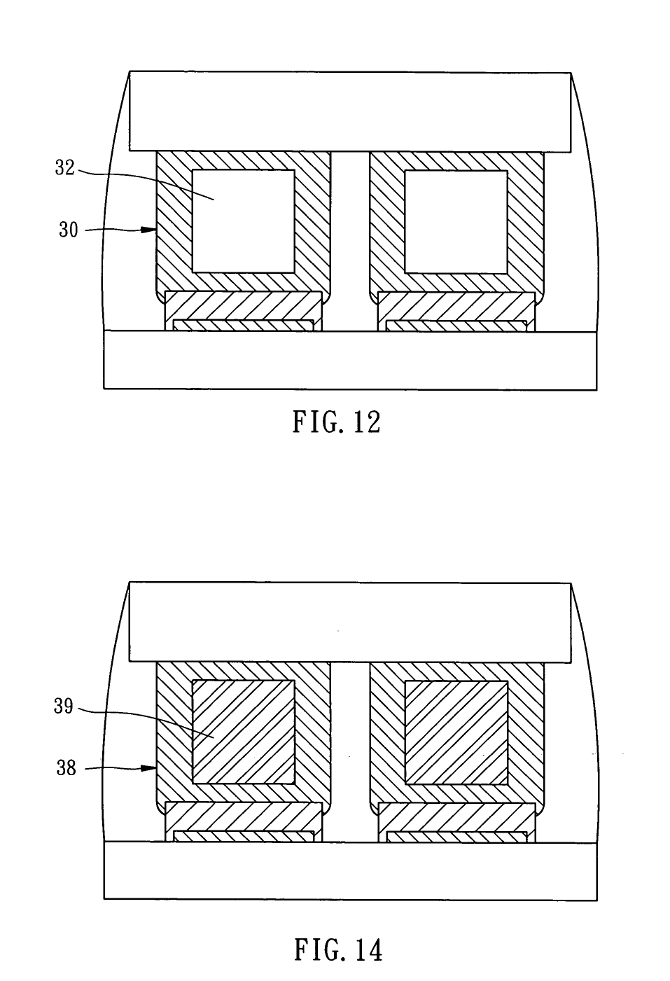

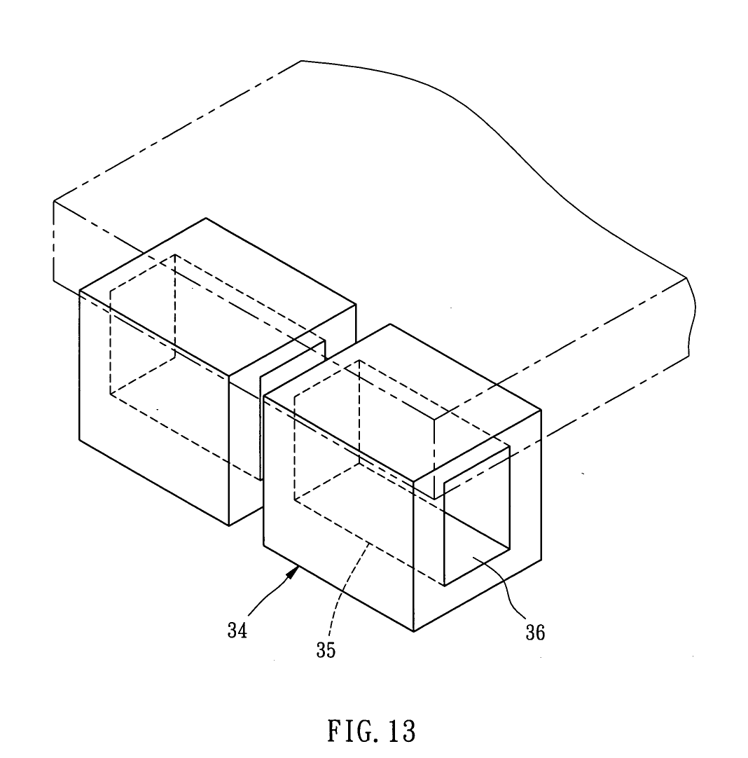

It is noted that the structures of the flip chip bump shown in FIG. 6 to FIG. 11 may be incorporated in the bump pads of the integrated circuit chip. FIG. 12 shows a bump pad 30 having a chamber 32 therein. FIG. 13 shows a bump pad 34 having lateral bores 36 communicated with a chamber 35 therein. FIG. 14 shows a bump pad 38 having an insulating member 39 therein. Above structures do not affect the eutectic bonding of the flip chip bumps and the bump pads, they increase the stability of eutectic bonding.

The description above is a few preferred embodiments of the present invention and the equivalence of the present invention is still in the scope of the claim of the present invention.

What is claimed is:

1. An optical display package, comprising:
a substrate including a glass plate, a plurality of oxide wires on the glass plate and a plurality of flip chip bumps bonded to the oxide wires respectively; and
an integrated circuit chip including a plurality of bump pads aligned with the flip chip bumps of the substrate, wherein the substrate and the integrated circuit chip are hot pressed to bond the bump pads to the flip chip bumps respectively by eutectic bonding.

2. The optical display package as defined in claim 1, further comprising a non-conductive film between the substrate and the integrated circuit chip bond the substrate and the integrated circuit chip together.

3. The optical display package as defined in claim 1, wherein the flip chip bumps of the substrate are made of a material chosen from silver, copper, tin, nickel, aluminum, lead, and alloys thereof.

4. The optical display package as defined in claim 1, wherein the bump pads of the integrated circuit chip are made of a material chosen from silver, copper, tin, nickel, aluminum, lead, and alloys thereof.

5. The optical display package as defined in claim 1, wherein the flip chip bump of the substrate has a chamber therein.

6. The optical display package as defined in claim 5, further comprising an insulating member received in the chamber of the flip chip bump.

7. The optical display package as defined in claim 5, wherein the flip chip bump of the substrate further has at least a lateral bore communicated with the chamber.

8. The optical display package as defined in claim 1, wherein the bump pad of the integrated circuit chip has a chamber therein.

9. The optical display package as defined in claim 8, further comprising an insulating member received in the chamber of the bump pad.

10. The optical display package as defined in claim 8, wherein the bump pad of the integrated circuit chip further has at least a lateral bore communicated with the chamber.

11. A method of packaging an optical display, comprising the steps of:
preparing an integrated circuit chip with a plurality of bump pads thereon and a glass plate with a plurality of flip chip bumps thereon;
aligning the integrated circuit chip with the glass plate and contacting the bump pads with the flip chip bumps respectively;
applying a bonding pressure less than 500 MPa on the integrated circuit chip in a bonding temperature of less than 400° C. to bond the bump pads with the flip chip bumps respectively by eutectic bonding.
